(19) United States
(12) Patent Application Publication
(10) Pub. No.: US 2025/0321502 A1
(43) Pub. Date: Oct. 16, 2025

(54) RETICLE CONTAINER FOR NON-EQUILATERAL RECTANGLE RETICLE

(71) Applicant: GUDENG PRECISION INDUSTRIAL CO., LTD., New Taipei (TW)

(72) Inventors: Ming-Chien Chiu, New Taipei (TW); Chia-Ho Chuang, New Taipei (TW); Ping-Cheng Chen, New Taipei (TW); Yen-Cheng Tu, New Taipei (TW); Hsin-Min Hsueh, New Taipei (TW); Chang-Da Liu, New Taipei (TW); Jie-Ru Ming, New Taipei (TW)

(21) Appl. No.: 19/090,593

(22) Filed: Mar. 26, 2025

Related U.S. Application Data
(60) Provisional application No. 63/632,587, filed on Apr. 11, 2024.

(51) Int. Cl. G03F 7/00; G03F 1/66

(52) U.S. Cl. CPC G03F 7/70741; G03F 1/66

(57) ABSTRACT

The invention relates to a non-equilateral reticle container which can be a dual pod, especially an outer pod of the dual pod whose length and width are 1.25 to 2.5 times of a length and a width of a non-equilateral reticle. An inner pod of the dual pod has a length and a width that are 10.5 to 2.0 times of the length and the width of a non-equilateral reticle. The outer pod includes a gas diffusion device having a flow path and a gas diffusor component. The flow path delivers the gas to the gas diffusor component to blow the gas toward a lid of the inner pod. The outer pod and the inner pod, within a center area thereof, have corresponding windows for observation so as to provide a partial observation for a non-equilateral reticle and a pellicle in the container.

### CROSS-REFERENCE TO RELATED APPLICATIONS

This application claims priority to U.S. Provisional Patent Application No. 63/632,587 filed in U.S. on Apr. 11, 2024 the entire contents of which are hereby incorporated by reference.

### BACKGROUND OF THE INVENTION

### Field of the Invention

The present disclosure relates to reticle containers, and more particularly to an extreme ultraviolet (EUV) reticle transfer container for semiconductor equipment, especially a non-equilateral rectangular reticle container for receiving a non-equilateral rectangular EUV reticle.

### Description of the Prior Art

As the feature size and resolution of new process nodes continue to shrink, the device density and number on advanced semiconductor reticles are rapidly increasing. Extreme Ultraviolet (EUV) lithography technology has become a key technology in the semiconductor industry. Extreme ultraviolet light is a type of light with a wavelength shorter than 13.5 nanometers. An aligner that uses EUV as the light source is known as an EUV aligner/lithography machine (collectively known as EUV equipment). The miniaturization of integrated circuits is further advanced by using light with an extremely small wavelength to print microchips. It is crucial to develop the lithography technology of high-numerical aperture extreme ultraviolet (High-NA EUV), for example, increasing numerical aperture (NA) from 0.33 to 0.55 or above, to further shrink equipment nodes and achieve smaller features.

The purpose of developing high-numerical aperture (High-NA) aligners is to attain higher resolution imaging capability, print more microchips with improved precision and clearer imaging, and enhance the production capacity and yield of advanced manufacturing processes. Expectedly, the development of High-NA EUV equipment enables the continuous scaling of line width in semiconductor manufacturing. However, compared to conventional numerical aperture (NA) exposure imaging, High-NA EUV results in a smaller, or even halved, exposure imaging area on a wafer due to optical characteristics of High-NA EUV. In reticle development, the reticle size needs to be enlarged sufficiently to effectively cover the exposure imaging area on the wafer. Therefore, the existing equilateral rectangular reticle size must be replaced with a larger non-equilateral rectangular reticle size to accommodate High-NA EUV lithography technology, achieving smaller nanometer-scale, or even angstrom-scale, processing. In addition to changing the structural design of the non-equilateral rectangular reticle, it is also necessary to revolutionize the original structural design of the rectangular reticle containers. An effective reticle transport solution for large-sized non-equilateral rectangular reticle containers in brand-new technological domains must be proposed in order to enable a major technological breakthrough for advanced manufacturing processes.

### SUMMARY OF THE INVENTION

The disclosure provides a non-equilateral rectangular reticle container for receiving a non-equilateral rectangular reticle. The non-equilateral rectangular reticle container comprises an outer pod comprising a shell and a door, both capable of opening and closing relative to each other. The shell and the door each have a length and a width and together define a receiving space. The non-equilateral rectangular reticle container comprises an inner pod comprising a cover and a base, both capable of opening and closing relative to each other. The cover and the base each have a length and a width. The inner pod is located inside the receiving space of the outer pod and configured to receive the non-equilateral rectangular reticle. The length of the outer pod is 1.25 to 2.5 times the length of the non-equilateral rectangular reticle. The width of the outer pod is 1.25 to 2.5 times the width of the non-equilateral rectangular reticle. The length of the inner pod is 1.05 to 2.0 times the length of the non-equilateral rectangular reticle. The width of the inner pod is 1.05 to 2.0 times the width of the non-equilateral rectangular reticle.

The disclosure further provides a non-equilateral rectangular reticle container, for receiving a non-equilateral rectangular reticle, comprising: an outer pod comprising a shell and a door, both capable of opening and closing relative to each other, with the shell and the door each having a length and a width and together defining a receiving space; an inner pod comprising a cover and a base, both capable of opening and closing relative to each other, with the cover and the base each having a length and a width, with the inner pod located inside the receiving space of the outer pod and configured to receive the non-equilateral rectangular reticle; and a gas diffusion device disposed inside the outer pod and comprising a flow path and a gas diffusion component in communication with each other and disposed between the shell and the door, allowing the flow path to deliver gas to the gas diffusion component to blow the gas toward the cover of the inner pod. The length of the outer pod is 1.25 to 2.5 times a length of the non-equilateral rectangular reticle, and the width of the outer pod is 1.25 to 2.5 times a width of the non-equilateral rectangular reticle. The length of the inner pod is 1.05 to 2.0 times a length of the non-equilateral rectangular reticle, and the width of the inner pod is 1.05 to 2.0 times a width of the non-equilateral rectangular reticle.

The disclosure further provides a non-equilateral rectangular reticle container, for receiving a non-equilateral rectangular reticle, comprising: an outer pod comprising a shell and a door, both capable of opening and closing relative to each other, wherein the shell and the door each have a length and a width and together define a receiving space; an inner pod comprising a cover and a base, both capable of opening and closing relative to each other, wherein the cover and the base each have a length and a width, with the inner pod located inside the receiving space of the outer pod and configured to receive the non-equilateral rectangular reticle; and at least two observation windows disposed on the door and the base respectively and corresponding in position to each other. The base has a central area where the observation window is located. The central area is defined by a length 0.9 times the length of the non-equilateral rectangular reticle and by a width 0.9 times the width of the non-equilateral rectangular reticle. The observation window of the door aligns with at least a portion of the central area of the base. The observation window of the door and the observation window of the base are for use in directly observing the non-equilateral rectangular reticle and a pellicle. The length of the outer pod is 1.25 to 2.5 times the length of the non-equilateral rectangular reticle. The width of the outer pod is 1.25 to 2.5 times the width of the non-equilateral rectangular reticle. The length of the inner pod is 1.05 to 2.0 times the length of the non-equilateral rectangular reticle. The width of the inner pod is 1.05 to 2.0 times the width of the non-equilateral rectangular reticle.

The disclosure further provides a non-equilateral rectangular reticle container, for receiving a non-equilateral rectangular reticle, comprising a shell and a door. The door and the shell are capable of opening and closing relative to each other and define a receiving space. The door and the shell have the same length and width. The receiving space receives the non-equilateral rectangular reticle. The length and the width are 1.25 to 2.5 times the length of the non-equilateral rectangular reticle.

### BRIEF DESCRIPTION OF THE DRAWINGS

The disclosure is depicted by drawings, illustrated by non-restrictive, non-exhaustive embodiments, and described below. The drawings are not drawn to scale but are aimed at disclosing the structural features and principles of the disclosure.

FIG. 1A illustrates a non-equilateral rectangular reticle container according to an embodiment of the disclosure.

FIG. 1B is an exploded view of the non-equilateral rectangular reticle container according to an embodiment of the disclosure.

FIG. 1C is a partial cross-sectional view of a door.

FIG. 1D illustrates a partial edge of the door.

FIG. 1E illustrates a means of automatic locking provided by a shell and the door.

FIG. 1F illustrates a resilient holding component.

FIG. 2A is a top view of an outer pod.

FIG. 2B is a top view of an inner pod.

FIG. 3A schematically illustrates a means of observation of the non-equilateral rectangular reticle container of the disclosure.

FIG. 3B illustrates an installation range of an observation window of the inner pod.

FIG. 4A illustrates the layout on an upward-facing surface of the door of the outer pod.

FIG. 4B illustrates the layout on the bottom of the door of the outer pod.

FIG. 4C illustrates the layout on an upward-facing surface of a base of the inner pod.

FIG. 4D illustrates the layout on the bottom of the base of the inner pod.

FIG. 4E is a partial cross-sectional view of the door and the base coupled together.

FIG. 5A illustrates a means of environmental control of the non-equilateral rectangular reticle container of the disclosure.

FIG. 5B illustrates the layout of the inner side of the shell.

FIG. 5C illustrates the layout of the upward-facing surface of the door.

FIG. 6A is a partial cross-sectional view of the shell and the door before being coupled together.

FIG. 6B is a partial cross-sectional view of the shell and the door after being coupled together.

FIG. 7A illustrates the inner pod having a means of filtering.

FIG. 7B is a top view of the overlapping relationship between a gas diffusion component and the means of filtering.

FIG. 8A illustrates the layout on the top of a cover of the inner pod.

FIG. 8B illustrates the layout on the inner side of the inner pod.

FIG. 8C is an enlarged view of the shell coupled to the cover, showing that a protrusion of the shell corresponds in position to a dent of the cover.

FIG. 9 is a schematic view of a support structure of the base.

FIG. 10 is a schematic view of another aspect of the support structure of the base.

FIG. 11 is a schematic view of another aspect of the support structure of the base.

### DETAILED DESCRIPTION OF THE EMBODIMENTS

The disclosure is depicted by accompanying drawings, illustrated by specific embodiment and described below. However, the subject matter claimed by the disclosure can be implemented in various ways; hence, the subject matter falling within the scope of or claimed by the disclosure is not restricted to any specific embodiments of the disclosure. The specific embodiments of the disclosure serve illustrative purposes only. Likewise, the disclosure is aimed at defining reasonably broad scope of the subject matter falling within the scope of or claimed by the disclosure.

The expression “in an embodiment” used herein does not necessarily refer to the same specific embodiment. Furthermore, the expression “in other (a few/some) embodiments” used herein does not necessarily refer to different specific embodiments. The expressions are aimed at, for example, enabling the claimed subject matter to include the combination of all or part of exemplary, specific embodiments. The meanings of the expression “coupled” used herein include “directly connected” or “indirectly connected.”

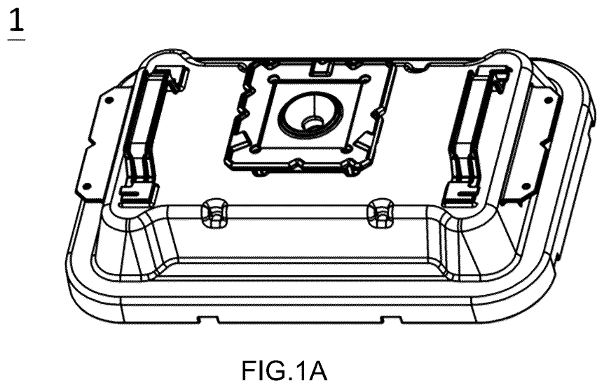

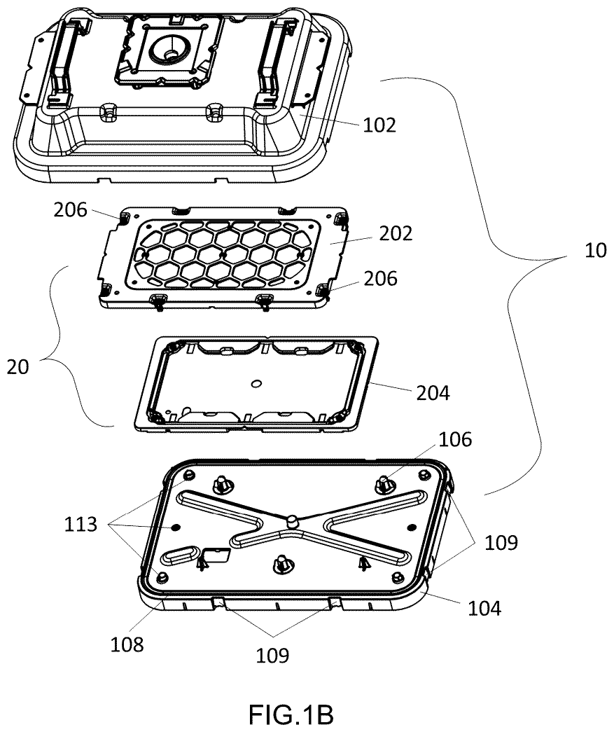

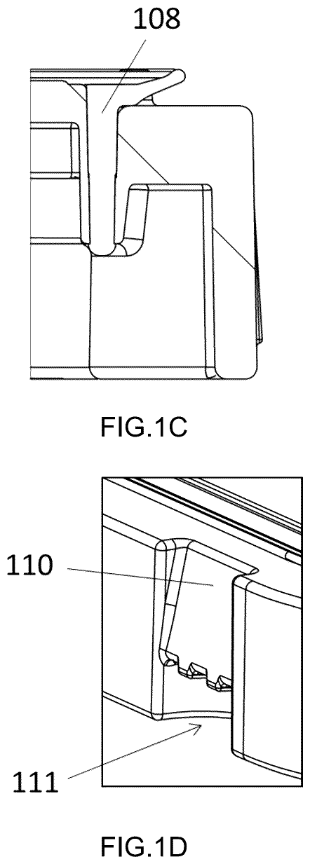

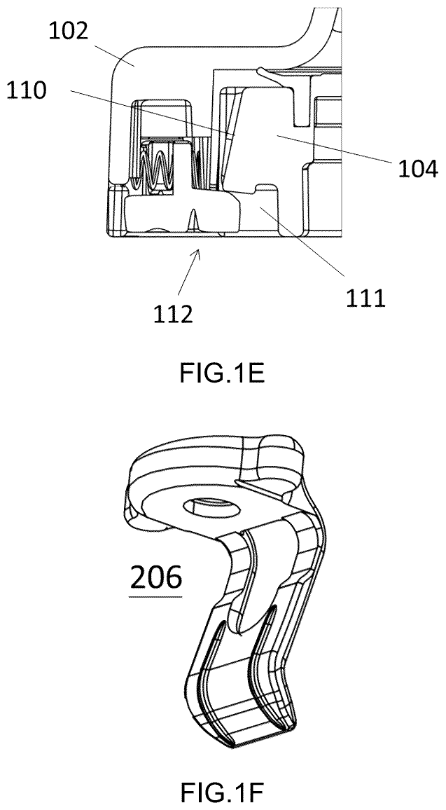

Refer to FIG. 1A and FIG. 1B simultaneously. FIG. 1A illustrates a specific embodiment of a non-equilateral rectangular reticle container (1) of the disclosure. FIG. 1B is an exploded view of the non-equilateral rectangular reticle container (1). The non-equilateral rectangular reticle container (1) is a non-equilateral rectangular dual pod comprising an outer pod (10) and an inner pod (20), both in non-equilateral rectangular shape. In an embodiment, the non-equilateral rectangular reticle received in the reticle container (1) is a 6-inch×12-inch reticle or a reticle with an aspect ratio of approximately 1:1.86 to 2.5, but the disclosure is not limited thereto. The outer pod (10) has structural features compatible with an overhead hoist transport (OHT) system in the factory to allow a reticle received in the outer pod (10) and the inner pod (20) to be transferred between factory devices.

The outer pod (10) comprises a shell (102) and a door (104). The shell (102) comprises wall surfaces which together enclose a space with an opening. The opening faces downward or laterally. The door (104) is used to close off the opening of the shell (102). The ceiling of the shell (102) further has features compatible with the OHT system and a handle to be gripped by a worker. In this embodiment, the opening of the shell (102) of the outer pod (10) faces downward, and an upward-facing surface of the door (104) has a means of carrying for allowing the inner pod (20) to be mounted on the upward-facing surface. Alternatively, the opening of the shell (102) of the outer pod (10) faces laterally, and the shell (102) has a means of carrying for holding the inner pod (20) inside the space. Regardless of whether the opening of the shell (102) of the outer pod (10) faces downward or laterally, the outer pod (10) comprises the shell (102) and the door (104), both capable of opening and closing relative to each other, with the shell (102) having a length and a width, and with a receiving space jointly defined by the opening of the shell (102) and the door (104).

The inner pod (20) comprises a cover (202) and a base (204), both capable of opening and closing relative to each other. The cover (202) and the base (204) each have a length and a width. The inner pod (20) is disposed in the receiving space of the outer pod (10). The inner pod (20) receives a non-equilateral rectangular reticle (not shown).

In order to be distinguished from known equilateral rectangular reticles, non-equilateral rectangular reticles have larger dimensions and thus necessitate redefining the dimensions of non-equilateral rectangular reticle containers. The non-equilateral rectangular reticle container of the disclosure has non-equilateral structural features as follows: the length and width of the outer pod (10) are 1.25 to 2.5 times those of the non-equilateral rectangular reticle, and the length and width of the inner pod (20) are 1.05 to 2.0 times those of the non-equilateral rectangular reticle.

Three dynamic coupling pins (106) are disposed on the upward-facing surface of the door (104) and can be coupled to the bottom of the inner pod (20). The upward-facing surface of the door (104) further has a means of hermetic sealing for allowing a receiving space defined by the shell (102) and the door (104) to achieve a hermetic seal to a considerable extent. The upward-facing surface of the door (104) further has a sealing ring (108). As shown in FIG. 1C, a portion of the sealing ring (108) is embedded in the door (104), and an exposed portion of the sealing ring (108) touches against a downward-facing surface of the shell (102) to form a hermetic seal. The shell (102) or the door (104) further has a means of observation for allowing a recognition device to observe the state inside the receiving space from beneath the door (104), as described later. The shell (102) and the door (104) further have a means of automatic locking. A plurality of guiding slots (109) are disposed on the lateral sides of the edges of the door (104). As shown in FIG. 1D, the guiding slot (109) has a slope (110), and a recess (111) is disposed under the slope (110).

FIG. 1E is a cross-sectional view of the guiding slot (109), showing that the shell (102) and the door (104) are coupled together. A resilient locking component (112) comprising a spring and a slider is disposed at a sidewall edge of the shell (102) and corresponds in position to the guiding slot 109 shown in FIG. 1B, but the disclosure is not limited thereto. The resilient locking component (112) switches between a fully released state and a compressed state. When the shell (102) approaches the door (104), the slider of the resilient locking component (112) comes into contact with the top end of the slope (110) and is guided by the slope (110). As the shell (102) and the door (104) move closer to each other, the slider of the resilient locking component (112) slides downward along the slope (110) and while being laterally pushed to cause the compression of the spring; after passing the bottom of the slope (110), the slider is released into the recess (111), allowing the shell (102) to be locked to the door (104). The shape of the resilient locking component (112) is appropriately designed in a manner conducive to the reduction of the hindrance to the slider's entry into the recess (111) along the slope (110). An unlocking process entails separating the resilient locking components (112) from the recess (111) to facilitate the separation of the shell (102) from the door (104).

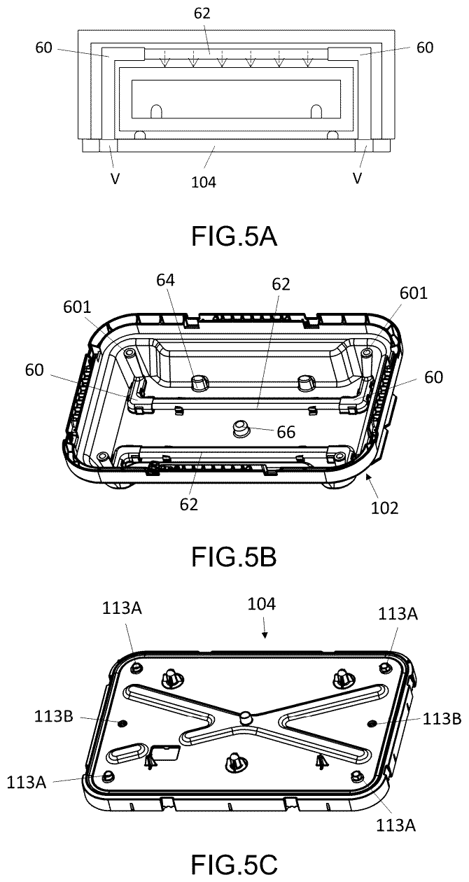

The door (104) further has a means of environmental control for controlling humidity and pressure. As shown in FIG. 1B, the upward-facing surface of the door (104) has a plurality of openings (113) which can be configured to function as filling openings or absorbing openings. Pores in communication with the plurality of openings (113) are disposed at the bottom of the door (104) and connected to a gas system of equipment. As shown in FIG. 5B, the door (104) further comprises a plurality of valve assemblies (V) corresponding in position to the openings (113) to individually control the activation and shutdown of airflow.

The inner pod (20) essentially comprises machined components, namely the cover (202) and the base (204). The cover (202) comprises a top and a sidewall and has a means of filtering for allowing the gas contained inside the outer pod (10) to diffuse to the inner pod (20), as described later. A means of displacement restriction is disposed on the inner side of the cover (202) to restrict the horizontal and vertical displacements of the reticle. An upward-facing surface of the base (204) has a means of support for supporting the bottom of the reticle or restricting the lateral displacement of the reticle. The base (204) further has a means of observation for allowing a recognition device to observe the state of the bottom of the reticle from beneath the base (204). The cover (202) further has a means of resilient restriction. As shown in FIG. 1B, the four edges of the cover (202) have a plurality of resilient holding components (206), one of which is shown in the enlarged view FIG. 1F. The resilient holding components (206) each comprise a fixed end and a bent arm. When the cover (202) approaches the base (204), the bent arms of the resilient holding components (206) slide downward across the surfaces of the four edges of the base (204) until a downward-facing surface of the cover (202) comes into contact with the upward-facing surface of the base (204). The resilient holding component (206) is manufactured through a molding process and has considerable resilience. The resilient holding components (206) at the four edges of the cover (202) touch against the four edges of the base (204), preventing the cover (202) from undergoing horizontal displacement relative to the base (204).

In this embodiment, the non-equilateral rectangular reticle container is a dual pod such that having the inner pod (20) received by the outer pod (10) allows the length of the outer pod (10) to be substantially parallel to the length of the inner pod (20) and allows the width of the outer pod (10) to be substantially parallel to the width of the inner pod (20).

In another embodiment, the non-equilateral rectangular reticle container of the disclosure is a single pod for receiving a non-equilateral rectangular reticle. The non-equilateral rectangular reticle container comprises a shell and a door. The door and the shell are capable of opening and closing relative to each other and define a receiving space. The door and the shell are equal in length and width. The receiving space receives the non-equilateral rectangular reticle. To distinguish the non-equilateral rectangular reticle container of the disclosure from conventional equilateral rectangular reticle containers in terms of structural features of a single pod, the non-equilateral rectangular reticle container of the disclosure is characterized in that the length and width of the door and the shell are 1.25 to 2.5 times the length of the non-equilateral rectangular reticle.

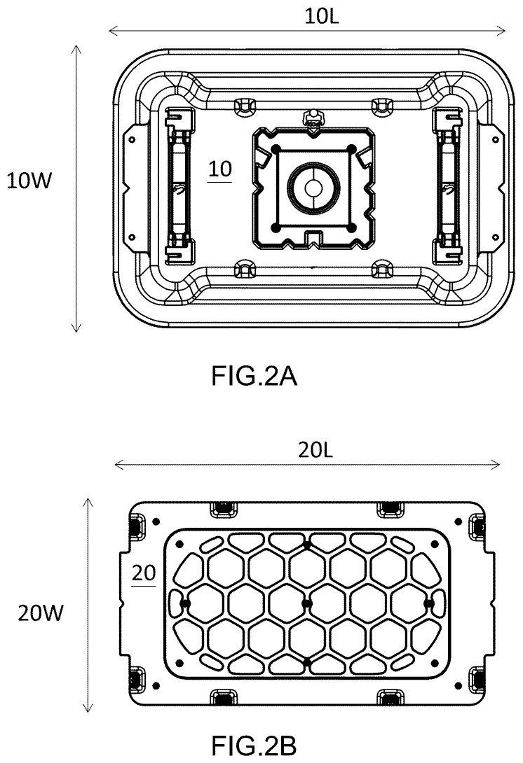

FIG. 2A illustrates measurement definitions of a length (10L) and a width (10 W) of the outer pod (10). FIG. 2B illustrates measurement definitions of a length (20L) and a width (20 W) of the inner pod (20). The length (10L) of the outer pod (10) extends between a pair of handles on the shell (102). The length (20L) of the inner pod (20) extends between a pair of flanges of the cover (202).

In a specific embodiment, the length and width of the shell (102) are 19˜21 inches and 12˜14 inches respectively, whereas the length and width of the door are 16˜18.9 inches and 11˜13.9 inches respectively, but the disclosure is not limited thereto. In a variant embodiment, the length and width of the shell (102) and the door are adjustable as needed.

In a specific embodiment, the length and width of the cover (202) are 14˜16 inches and 7˜9 inches respectively, whereas the length and width of the base (204) are 12˜15 inches and 6˜8.9 inches respectively, but the disclosure is not limited thereto. In a variant embodiment, the length and width of the cover (202) and the base (204) are adjustable as needed.

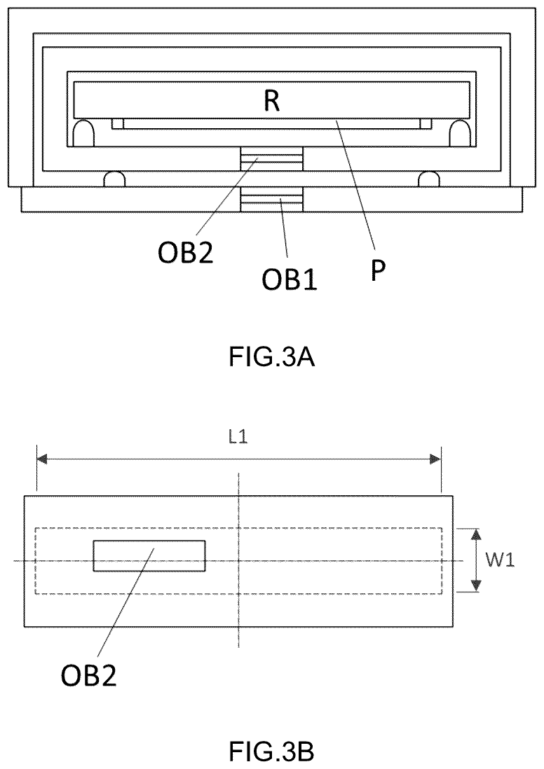

FIG. 3A illustrates a means of observation provided by the reticle container, comprising a means of observation of the outer pod and a means of observation of the inner pod. When a reticle (R) is received in the inner pod of the reticle container, a pellicle (P) for protecting reticle patterns is adhered to the bottom of the reticle and spaced apart from the base of the inner pod by an appropriate distance. The non-equilateral rectangular reticle has greater pattern dimensions than those of conventional equilateral rectangular reticles; thus, the dimensions of the pellicle have to increase. The pellicle consists of a frame and a thin film, but the central region of the thin film lacks support from the frame; thus, the central region of a large-size thin film may undergo a large amount of deformation. In view of this, the means of observation is mainly disposed within the central regions of the outer pod and the inner pod to facilitate the observation of the deformation state of the pellicle. The means of observation of the outer pod comprises a first observation window (OB1), whereas the means of observation of the inner pod comprises a second observation window (OB2), with the first and second observation windows (OB1, OB2) corresponding in position to each other. Thus, a recognition device (for example, a lens) located under the reticle container can perform the observation on the central region of the pellicle (P) through the first observation window (OB1) and the second observation window (OB2).

FIG. 3B illustrates an installation range of the second observation window (OB2). The range is delineated by a rectangle defined by a length (L1) and a width (W1). A central position of the rectangle overlaps a central position of the base of the inner pod. In an embodiment, the length (L1) of the range is substantially 0.9 times the length of the non-equilateral rectangular reticle, and the width (W1) of the range is substantially 0.9 times the width of the non-equilateral rectangular reticle. At least a portion of the second observation window (OB2) must be located within the range. Regarding the first observation window (OB1), its projection range should, as a general rule, overlap at least a portion of the second observation window (OB2). The first observation window (OB1) and the second observation window (OB2) can be round, rectangular, polygonal or of any other irregular shape.

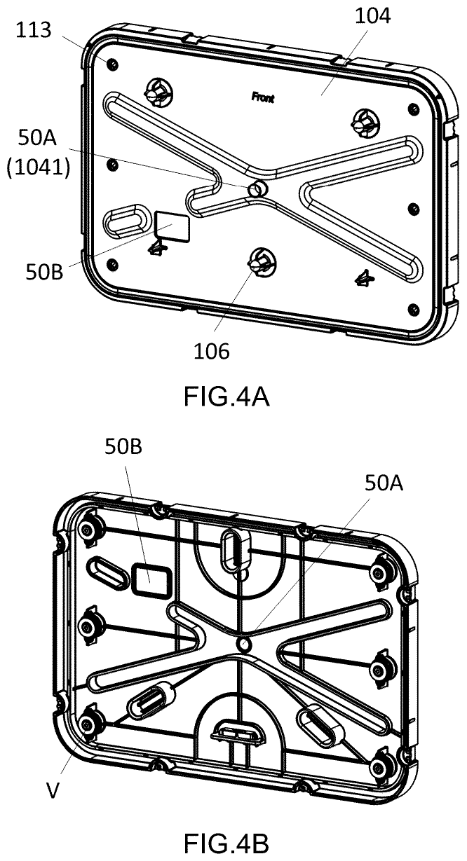

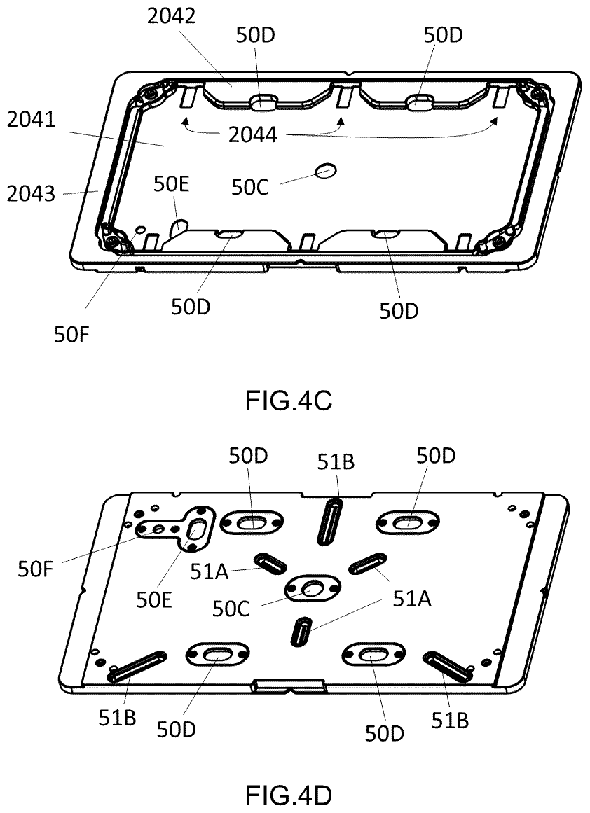

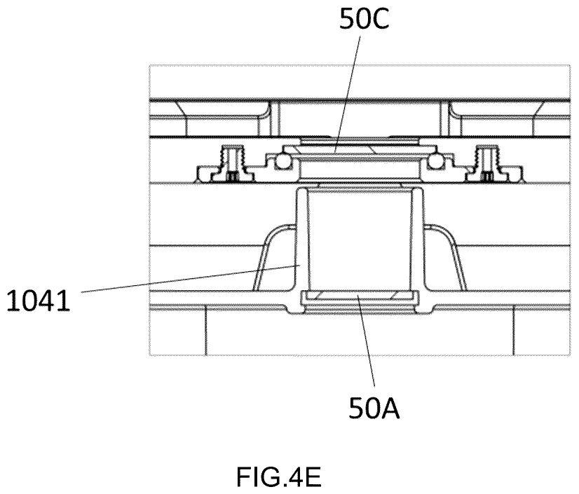

Referring to FIG. 4A and FIG. 4B, in a specific embodiment, a central observation window (50A) is centrally disposed on the door (104) and exemplified by a round observation window. Another observation window (50B) is further disposed between the center and the periphery of the door (104) and exemplified by a rectangular observation window. The observation window (50E) of the base (204) corresponds in position to the central observation window (50A) and the observation window (50B). The range of the observation window (50B) does not include the range of the central observation window (50A). A non-equilateral rectangular reticle, a pellicle frame and a pellicle exposed from the base (204) are observed by the observation window (50B) of the door (104) through the observation window (50E) of the base (204).

Referring to FIG. 4C and FIG. 4D, in a specific embodiment, the base (204) has a central observation window (50C) exemplified by a round observation window. The central observation window (50C) of the base (204) corresponds in position to the central observation window (50A) of the door (104) to facilitate observing and determining whether the central region of the pellicle deforms or sags. The base (204) further has observation windows (50D, 50E, 50F), with four observation windows (50D) each located at the junction between a reticle carrying surface (2041) and a corresponding one of four platforms (2042). The observation windows (50D) collectively function as a reticle pre-alignment system (RPAS) window whereby a reading device on a load port retrieves a plurality of alignment marks on the non-equilateral rectangular reticle through the observation windows (50D).

In a further embodiment, the observation windows (50D) are near the widthwise side of the base (204). The platforms (2042) are near the lengthwise side of the base (204). The platforms (2042) and a surrounding surface (2043) define a plurality of pellicle pockets (2044). The pellicle pockets (2044) prevent the pellicle frame and the base (204) from interfering with each other. The observation windows (50E, 50F) are located at a corner region of the reticle carrying surface (2041), with the observation windows (50E) being elliptical, and the observation windows (50F) being round. The observation windows (50E) and the observation windows (50F) differ significantly in dimensions and are used to observe the reticle, the pellicle frame, and a pellicle. In the embodiment illustrated by FIG. 4D, an inner positioning recess component (51A) and an outer positioning recess component (51B) are disposed on the bottom surface of the base (204) and surround the central observation window (50C) or a central position. The inner positioning recess component (51A) and the outer positioning recess component (51B) each comprise three groove components operating in conjunction with the dynamic coupling pins, i.e., the dynamic coupling pins (106) or other dynamic coupling pins of the load port (as shown in FIG. 4A).

According to the disclosure, the observation windows are integrated with a support mechanism. FIG. 4E is a partial cross-sectional view of the door (104) and the base (204) coupled together. When the base (204) is placed above the dynamic coupling pins (106) of the door (104), a reinforced support component (1041) is disposed on the inner side of a bottom of the door (104) to support the inner pod (20). The reinforced support component (1041) of the door (104) presses against the center of the base (204). As shown in the cross-sectional view, the reinforced support component (1041) is a hollow-core cylindrical structure protruding from the inner side of the door (104). The central observation window (50A) is integrated into the reinforced support component (1041) in any known manner. In this embodiment, the central observation window (50A) is confined to an unroofed space of the hollow-core cylindrical structure. The central observation window (50C) of the base (204) corresponds in position to the reinforced support component (1041). When the base (204) is placed on the door (104), the central observation window (50A) of the door (104) and the central observation window of the base (204) are aligned or overlapping in a protruding manner. Basically, the three dynamic coupling pins (106) on the door (104) are sufficient to support the base (204), and the reinforced support component (1041) functions as an additional means of support. When the central region of the base (204) sags slightly because of tolerance or deformation, the reinforced support component (1041) can support the central region of the base (204).

As mentioned before, the door (104) and the base (204) have observation windows corresponding in position to each other respectively. In another embodiment, when the opening of the shell (102) faces laterally, the shell (102) and the base (204) each have an observation window that corresponds in position to the one on the other. The base (204) has a central area where the observation window is located. The central area is defined by a length 0.9 times the length of the non-equilateral rectangular reticle and by a width 0.9 times the width of the non-equilateral rectangular reticle. The observation window of the shell (102) aligns with at least a portion of the central area of the base (204), allowing the observation window of the shell (102) and the observation window of the base (204) to be used to directly observe a non-equilateral rectangular reticle and a pellicle.

The disclosure further improves control over the internal environment of a reticle container. The means of environmental control of a conventional reticle container involves delivering an inert gas, or extreme clean dry air (XCDA), for example, nitrogen gas, to the hermetically sealed outer pod through openings on the door of the outer pod, and then allowing the gas to diffuse into the inner pod through a filtering component of the inner pod after the internal environment of the outer pod has attained a specific pressure. However, owing to the ever-increasing dimensions of reticle transfer containers, the time required for the gas to enter the inner pods is also increasing. Thus, the reticle container of the disclosure provides improved means to enhance the efficiency of gas diffusion.

FIG. 5A illustrates a means of environmental control of the reticle container of the disclosure. As shown in the diagram, the outer pod (10) has therein a gas diffusion device. The gas diffusion device comprises at least a flow path (60) and at least a gas diffusion component (62) in communication with each other and disposed between the shell (102) and the door (104). The flow path (60) or one end of a manifold is coupled to the valve assenbly (V) of the door (104) to receive gas. The other end of the flow path (60) is coupled to the gas diffusion component (62). The flow path (60) delivers gas to the gas diffusion component (62) to blow the gas toward the cover (202) of the inner pod (20). Basically, the gas diffusion component (62) is not only located at the top of the receiving space of the outer pod (10) but also has a gas diffusion interface, allowing the gas to diffuse toward the top of the cover (202) of the inner pod (20). Once a pressure difference develops between the external environment and internal environment of the inner pod (20), the gas will be compelled to move into the inner pod (20) via the filtering component, achieving micro-environmental control over the inner pod (20).

FIG. 5B and FIG. 5C show a specific embodiment for a means of environmental control. As shown in FIG. 5B, the gas diffusion component (62) is disposed on the underside of a ceiling of the shell (102), whereas the flow path (60) is disposed at one end of the gas diffusion component (62) and extends along an inner sidewall of the shell (102) to an opening on the bottom of the door (104). In this embodiment, the flow path (60) and the gas diffusion component (62) are paired and disposed on the underside of the ceiling of the shell (102). The flow path (60) can be integrally formed with the shell (102). The flow path (60) has a receiving port (601). An air chamber is disposed in the flow path (60) or connected between the flow path (60) and the gas diffusion component (62) to collect gas and then supply the gas to the gas diffusion component (62). In a further embodiment, the air chamber is configured to collect gas from a plurality of receiving ports (601) or a plurality of flow paths (60) and supply the gas to one or more gas diffusion components (62). The flow path (60) extends from the receiving ports (601) along the sidewall to the ceiling of the shell (102). In a further embodiment, the flow path (60) is a detachable pipe. The gas diffusion component (62) is detachably fixed to the ceiling of the shell (102). The gas diffusion component (62) is a bar parallel to the long sides of the shell (102). The two ends of the gas diffusion component (62) are coupled to two flow paths (60) respectively. In a further embodiment, the gas diffusion component (62) can be of any other shape. The numbers and combinations of the flow paths (60) and the gas diffusion components (62) are not restricted to this embodiment.

Referring to FIG. 5C, the upward-facing surface of the door (104) has a plurality of openings (113A, 113B), including four intake openings (113A) and two exhaust openings (113B). The four receiving ports (601) of the shell (102) correspond in position to the four intake openings (113A). When the shell (102) and the door (104) are coupled together, the receiving ports (601) receive gas from the intake openings (113A). Therefore, after entering the outer pod (10), the gas is guided to the ceiling of the shell (102) and then diffuses downward from the ceiling. Since the cover (202) of the inner pod (20) has a filtering component, gathering a large amount of gas above the cover (202) is conducive to the diffusion of the gas into the inner pod (20) through a means of filtering of the cover (202) to enhance the efficiency of environmental control.

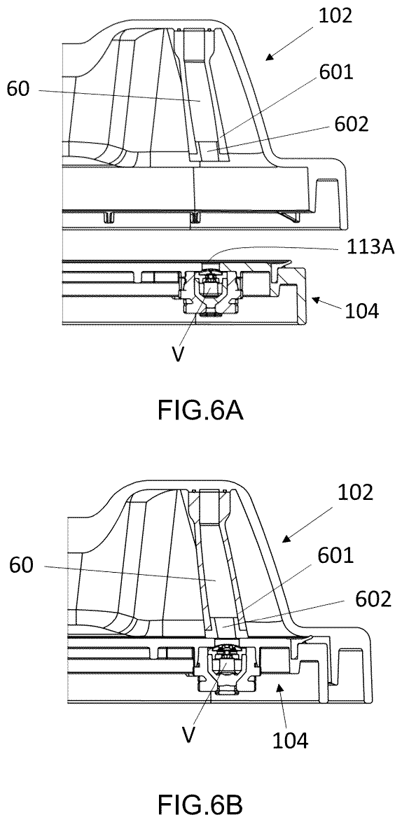

FIG. 6A and FIG. 6B are partial cross-sectional views, illustrating a means of environmental control in another embodiment. Disposed at the junction between the flow path (60) and the openings (113A) of the door (104) is a sealing element, such as a washer (602), which has resilience and is configured to be closely attached to the upward-facing surface of the door (104) when the shell (102) and the door (104) are coupled together, allowing the receiving ports (601) to be hermetically sealed. In a further feasible embodiment, the washer (602) is mounted on the intake openings (113A).

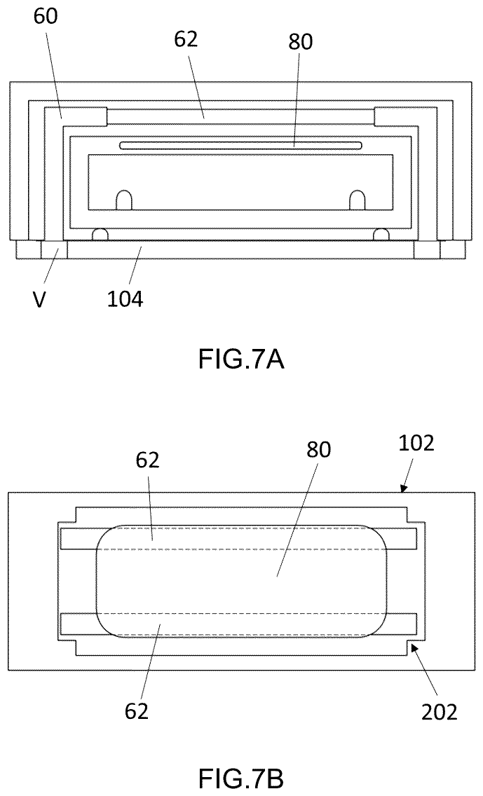

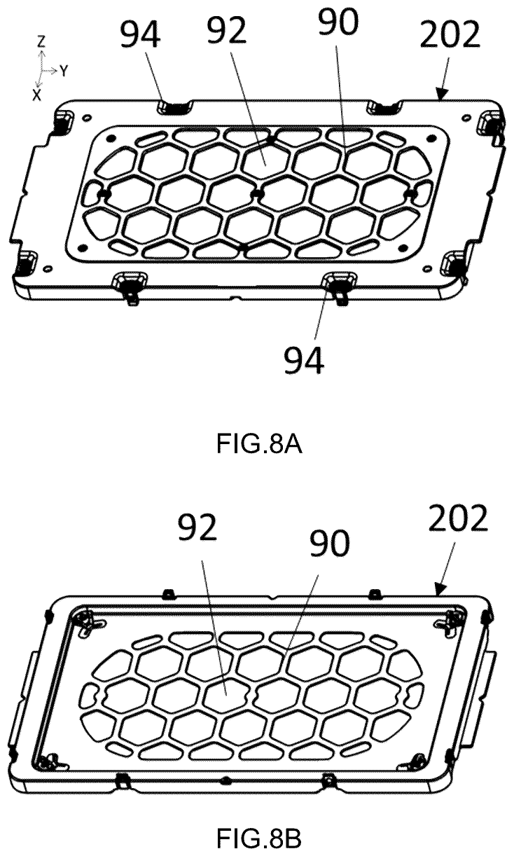

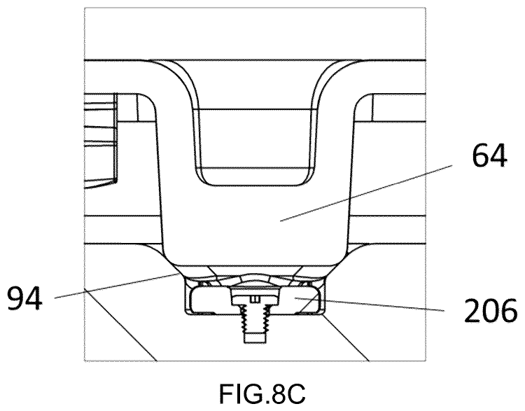

Referring to FIG. 7A, the cover of the inner pod has a means of filtering (80), and a specific embodiment thereof is illustrated by FIG. 8A and FIG. 8B. The means of filtering (80) comprises a plurality of hollowed-out portions (90) and a filtering component (92). Gas reaches the filtering component (92) via the hollowed-out portions (90). The filtering component (92) is a filtering thin film or porous component. Given a pressure difference, gas diffuses into the inner pod (20) or escapes from the inner pod (20), via the filtering component (92). FIG. 7B illustrates the relationship between the gas diffusion component (62) and the means of filtering (80) and, from a top-view angle, shows that the paired gas diffusion components (62) must overlap an effective range of the means of filtering (80) to ensure the rapid entry of gas into the inner pod (20). The length of the gas diffusion component (62) or diffusion pipe is greater than the length of the means of filtering (80) or filtering thin film to ensure that a blow region sufficiently aligns with the region of the means of filtering (80), enhancing diffusion efficiency. However, the disclosure is not limited thereto.

The reticle container of the disclosure further comprises tri-axle positioning members and directional positioning recesses for enhancing the positioning and stability of the inner pod.

FIG. 8A shows that the upward-facing surface of the cover (202) has a means of displacement restriction in a specific embodiment. Eight dents (94) are formed at four edges of the cover (202), with two dents (94) formed at each edge of the cover (202). As illustrated by the cross section shown in FIG. 8C, one end of the resilient holding component (206) is fixedly connected to the bottoms of the dents (94).

Referring to FIG. 5B, the means of displacement restriction further comprises a plurality of positioning protrusions (64) provided on the ceiling on the inner side of the shell (102). The protrusions (64) are arranged to correspond in position to the dents (94). When the shell (102) and the door (104) are coupled together, the protrusions (64) operate in conjunction with the corresponding ones of the dents (94). As shown in FIG. 8C, a lateral edge of each of the protrusions (64) is in contact with an inclined plane of a corresponding one of the dents (94) to attain positional restriction, allowing the protrusions (64) to restrain the cover of the inner pod in horizontal directions and a vertical direction indicated respectively by X-axis, Y-axis, and Z-axis shown in FIG. 8A. As shown in FIG. 5B, a central pressing component (66) is centrally disposed on the inner side of the shell (102) and configured to press against the center of the hollowed-out portions (90) to prevent the deflection of the hollowed-out portions (90). Therefore, the top center of the inner pod (20) is restrained by the central pressing component (66) from above and by the reinforced support component (1041) from below, stabilizing the inner pod (20).

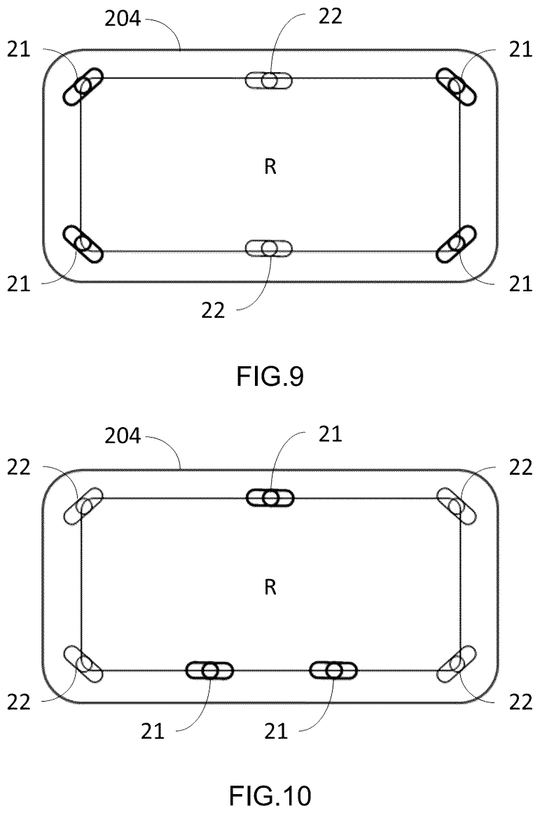

The non-equilateral rectangular reticle received in the reticle container (1) of the disclosure is 6 inches by 12 inches in size and thus is much larger than conventional square reticles. Thus, the 6-inch by 12-inch non-equilateral rectangular reticle being carried by the base (204) of the inner pod (20) is likely to rest on uneven support points and eventually warp. Referring to FIG. 9, there is shown a schematic view of a support structure of a base (204). The base (204) of the inner pod (20) further comprises a plurality of corner angle support elements (21) and at least two auxiliary support elements (22). The plurality of corner angle support elements (21) are located at corners of the base (204) respectively. Each of the auxiliary support elements (22) is located between two adjacent corner angle support elements (21). The two auxiliary support elements (22) are located at the lengthwise edges of the inner pod (20).

The plurality of corner angle support elements (21) are, for example, in the number of four and function as main support elements (21) for the non-equilateral rectangular reticle. The auxiliary support elements (22) made of a buffer material are disposed on the two long sides of the non-equilateral rectangular reticle and configured to provide auxiliary support for the non-equilateral rectangular reticle. When the non-equilateral rectangular reticle (R) is placed on the base (204), the auxiliary support elements (22) come into contact (first contact) with the non-equilateral rectangular reticle. Then, under the weight of the non-equilateral rectangular reticle, the auxiliary support elements (22) deform and slowly come into contact (second contact) with the four corner angle support elements (21) to provide uniform support for the non-equilateral rectangular reticle.

In another embodiment, the two auxiliary support elements (22) have their tops lower than the four corner angle support elements (21) and are disposed on the two long sides of the non-equilateral rectangular reticle. When the non-equilateral rectangular reticle is placed on the base (204), the four corner angle support elements (21) come into contact with the non-equilateral rectangular reticle, but the auxiliary support elements (22) do not directly come into contact with the non-equilateral rectangular reticle. When the non-equilateral rectangular reticle deforms as a result of long-term storage, the auxiliary support elements (22) come into contact with the non-equilateral rectangular reticle to suppress excessive deformation of the non-equilateral rectangular reticle.

In another embodiment, the two auxiliary support elements (22) are tilted auxiliary support elements or arc-shaped auxiliary support elements and are disposed on the two long sides of the non-equilateral rectangular reticle, and thus an inclined plane or an arc-shaped surface of each of the auxiliary support elements (22) comes into contact with the long sides of the non-equilateral rectangular reticle. When the non-equilateral rectangular reticle is placed on the base (204), the inclined planes or arc-shaped surfaces of the auxiliary support elements (22) come into contact (first contact) with the non-equilateral rectangular reticle. Then, under the weight of the non-equilateral rectangular reticle, a lower chamfered edge of the non-equilateral rectangular reticle slides downward slowly along the slopes of the tilted auxiliary support elements or arc-shaped auxiliary support elements to come into contact (second contact) with the four corner angle support elements (21) to provide uniform reticle support.

In another embodiment, the four corner angle support elements (21) and the two auxiliary support elements (22) are tilted auxiliary support elements or arc-shaped auxiliary support elements, and thus an inclined plane or an arc-shaped surface of each of the corner angle support elements (21) and the auxiliary support elements (22) comes into contact with the long sides and the short sides of the non-equilateral rectangular reticle. When the non-equilateral rectangular reticle is placed on the base (204), chamfered edges of the two auxiliary support elements (22) and the four corner angle support elements (21) slide downward slowly along the slopes of the tilted auxiliary support elements or arc-shaped auxiliary support elements and get positioned in place to provide uniform reticle support.

Referring to FIG. 10, there is shown a schematic view of another aspect of the support structure of the base (204). The main support elements (21) provide main support for the non-equilateral rectangular reticle and are disposed on the two long sides of the non-equilateral rectangular reticle. The four auxiliary support elements (22) are disposed at the corners of the base (204) and made of a buffer material to provide auxiliary support for the non-equilateral rectangular reticle. When the non-equilateral rectangular reticle (R) is placed on the base (204), the four auxiliary support elements (22) located at the corners come into contact (first contact) with the non-equilateral rectangular reticle. Then, under the weight of the reticle, the four buffering auxiliary support elements (22) deform to cause the reticle to slowly come into contact (second contact) with the main support elements (21) to provide uniform support for the non-equilateral rectangular reticle.

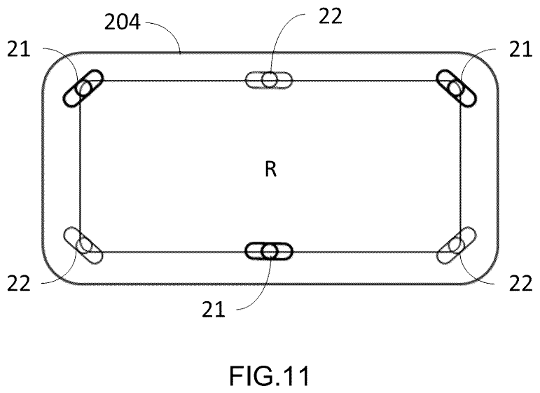

Referring to FIG. 11, there is shown a schematic view of another aspect of the support structure of the base (204). A plurality of main support elements (21) are disposed at two corners and a long side of the base (204) to achieve triangular distribution. A plurality of auxiliary support elements (22) correspond in position to the plurality of main support elements (21). Likewise, the plurality of auxiliary support elements (22) are disposed at two corners and a long side of the base (204) to achieve triangular distribution. The three support points formed by the plurality of main support elements (21) provide main support for the non-equilateral rectangular reticle. The three support points formed by the plurality of auxiliary support elements (22) are made of a buffer material and configured to provide auxiliary support for the non-equilateral rectangular reticle. When the non-equilateral rectangular reticle (R) is placed on the base (204), the plurality of auxiliary support elements (22) come into contact (first contact) with the reticle. Then, under the weight of the reticle, the buffering auxiliary support elements (22) deform and slowly come into contact (second contact) with the plurality of main support elements (21) at the other three support points to provide uniform reticle support.

The corner angle support elements or main support elements (21) are made of a material, including but not limited to Polyether Ether Ketone (PEEK), Polyetherimide (PEI), Polyamide-imide (PAI), Polyimide (PI), and a mixture thereof. The auxiliary support elements (22) are made of a material, including but not limited to Polyethylene (PE), Polypropylene (PP), Polyethylene Terephthalate (PET), Thermoplastic Elastomer (TPR), Thermoplastic Polyester Elastomer (TPEE), Fluoroelastomer (FKM), and Liquid Silicone Rubber (LSR). The material which the corner angle support elements (21) are made of and the material which the auxiliary support elements (22) are made of are interchangeable. Alternatively, the corner angle support elements (21) and the auxiliary support elements (22) are made of the same material. Whatever combinations or changes of the materials which the corner angle support elements (21) and the auxiliary support elements (22) are made of are not only applicable to the embodiments illustrated by FIG. 9 through FIG. 11 but also deemed to fall within the scope of the claims of the disclosure.

The disclosure is disclosed above by specific embodiments. However, the embodiments are illustrative of the disclosure only. Changes made to the embodiments without departing from the claims and the spirit of the disclosure must be deemed to fall within the scope of the claims of the disclosure. Therefore, the embodiments are not restrictive of the disclosure, and the genuine scope and spirit of the disclosure shall be defined by the appended claims.

What is claimed is:

1. A non-equilateral rectangular reticle container, for receiving a non-equilateral rectangular reticle, comprising:
an outer pod comprising a shell and a door, both capable of opening and closing relative to each other, wherein the shell and the door each have a length and a width and together define a receiving space; and
an inner pod comprising a cover and a base, both capable of opening and closing relative to each other, wherein the cover and the base each have a length and a width, with the inner pod located inside the receiving space of the outer pod and configured to receive the non-equilateral rectangular reticle,
wherein the length of the outer pod is 1.25 to 2.5 times a length of the non-equilateral rectangular reticle, and the width of the outer pod is 1.25 to 2.5 times a width of the non-equilateral rectangular reticle,
wherein the length of the inner pod is 1.05 to 2.0 times the length of the non-equilateral rectangular reticle, and the width of the inner pod is 1.05 to 2.0 times the width of the non-equilateral rectangular reticle.

2. The non-equilateral rectangular reticle container of claim 1, wherein the shell and the base each have an observation window that corresponds in position to the one on the other, with the base having a central area where the observation window is located, the central area being defined by a length 0.9 times the length of the non-equilateral rectangular reticle and by a width 0.9 times the width of the non-equilateral rectangular reticle, allowing the observation window of the shell to align with at least a portion of the central area of the base, allowing the non-equilateral rectangular reticle and a pellicle to be directly observed through the observation window of the shell and the observation window of the base.

3. The non-equilateral rectangular reticle container of claim 1, wherein the door and the base each have an observation window that corresponds in position to the one on the other, with the base having a central area where the observation window is located, the central area being defined by a length 0.9 times the length of the non-equilateral rectangular reticle and by a width 0.9 times the width of the non-equilateral rectangular reticle, allowing the observation window of the door to align with at least a portion of the central area of the base, allowing the non-equilateral rectangular reticle and a pellicle to be directly observed through the observation window of the door and the observation window of the base.

4. The non-equilateral rectangular reticle container of claim 1, wherein an observation window of the door and an observation window of the base correspond in position to each other and are used to observe the non-equilateral rectangular reticle, a pellicle frame, and a pellicle.

5. The non-equilateral rectangular reticle container of claim 1, wherein the base further comprises a plurality of reticle pre-alignment system windows for retrieving an alignment mark on the non-equilateral rectangular reticle.

6. The non-equilateral rectangular reticle container of claim 1, wherein the base further comprises a plurality of pellicle pockets.

7. The non-equilateral rectangular reticle container of claim 1, wherein the base further comprises an inner positioning recess component, an outer positioning recess component or a combination thereof.

8. The non-equilateral rectangular reticle container of claim 1, wherein a reinforced support component is disposed on an inner side of a bottom of the door to support the inner pod.

9. The non-equilateral rectangular reticle container of claim 1, wherein a plurality of tri-axle positioning members are disposed on an inner side of the shell, and directional positioning recesses are disposed at a periphery of the cover, allowing the plurality of tri-axle positioning members to correspond in position to and fixedly abut the directional positioning recesses, and vice versa.

10. The non-equilateral rectangular reticle container of claim 1, wherein the door has a guiding slot, and the shell has a resilient locking component configured to be guided along the guiding slot so as to be positioned and locked in place.

11. The non-equilateral rectangular reticle container of claim 1, wherein the base of the inner pod further comprises a plurality of corner angle support elements located at corners of the base and at least two auxiliary support elements each located between two adjacent ones of the corner angle support elements.

12. The non-equilateral rectangular reticle container of claim 11, wherein the two auxiliary support elements are located at lengthwise edges of the inner pod.

13. A non-equilateral rectangular reticle container, for receiving a non-equilateral rectangular reticle, comprising:
an outer pod comprising a shell and a door, both capable of opening and closing relative to each other, wherein the shell and the door each have a length and a width and together define a receiving space;
an inner pod comprising a cover and a base, both capable of opening and closing relative to each other, wherein the cover and the base each have a length and a width, with the inner pod located inside the receiving space of the outer pod and configured to receive the non-equilateral rectangular reticle; and
a gas diffusion device disposed inside the outer pod and comprising at least a flow path and at least a gas diffusion component in communication with each other and disposed between the shell and the door, allowing the flow path to deliver gas to the gas diffusion component to blow the gas toward the cover of the inner pod,
wherein the length of the outer pod is 1.25 to 2.5 times a length of the non-equilateral rectangular reticle, and the width of the outer pod is 1.25 to 2.5 times a width of the non-equilateral rectangular reticle,
wherein the length of the inner pod is 1.05 to 2.0 times a length of the non-equilateral rectangular reticle, and the width of the inner pod is 1.05 to 2.0 times a width of the non-equilateral rectangular reticle.

14. The non-equilateral rectangular reticle container of claim 13, wherein the gas diffusion component is disposed on an underside of a ceiling of the shell, with the flow path disposed at an end of the gas diffusion component and extending along an inner sidewall of the shell to an opening on a bottom of the door.

15. The non-equilateral rectangular reticle container of claim 13, wherein an air chamber is disposed between the flow path and the gas diffusion component.

16. The non-equilateral rectangular reticle container of claim 14, wherein a sealing element is disposed at a junction between the flow path and the openings of the door.

17. The non-equilateral rectangular reticle container of claim 13, wherein the cover has a filtering component, and a gas blow range of the gas diffusion component is greater than an installation range of the filtering component.

18. The non-equilateral rectangular reticle container of claim 13, wherein the door and the base each have an observation window that corresponds in position to the one on the other, with the base having a central area where the observation window is located, the central area being defined by a length 0.9 times the length of the non-equilateral rectangular reticle and by a width 0.9 times the width of the non-equilateral rectangular reticle, allowing the observation window of the door to align with at least a portion of the central area of the base, allowing the non-equilateral rectangular reticle and a thin film of a pellicle to be directly observed through the observation window of the door and the observation window of the base.

19. The non-equilateral rectangular reticle container of claim 13, wherein the base further comprises a plurality of reticle pre-alignment system windows for retrieving an alignment mark on the non-equilateral rectangular reticle.

20. The non-equilateral rectangular reticle container of claim 13, wherein the base further comprises an inner positioning recess component, an outer positioning recess component or a combination thereof.

21. The non-equilateral rectangular reticle container of claim 13, wherein a reinforced support component is disposed on an inner side of a bottom of the door to support the inner pod.

22. A non-equilateral rectangular reticle container, for receiving a non-equilateral rectangular reticle, comprising:
an outer pod comprising a shell and a door, both capable of opening and closing relative to each other, wherein the shell and the door each have a length and a width and together define a receiving space;
an inner pod comprising a cover and a base, both capable of opening and closing relative to each other, wherein the cover and the base each have a length and a width, with the inner pod located inside the receiving space of the outer pod and configured to receive the non-equilateral rectangular reticle; and
at least two observation windows disposed on the door and the base respectively and corresponding in position to each other,
wherein the base has a central area where the observation window is located, the central area being defined by a length 0.9 times the length of the non-equilateral rectangular reticle and by a width 0.9 times the width of the non-equilateral rectangular reticle,
wherein the observation window of the door aligns with at least a portion of the central area of the base, allowing the non-equilateral rectangular reticle and a pellicle to be directly observed through the observation window of the door and the observation window of the base,
wherein the length of the outer pod is 1.5 to 2.5 times a length of the non-equilateral rectangular reticle, and the width of the outer pod is 1.5 to 2.5 times a width of the non-equilateral rectangular reticle, and
wherein the length of the inner pod is 1.05 to 2.0 times the length of the non-equilateral rectangular reticle, and the width of the inner pod is 1.05 to 2.0 times the width of the non-equilateral rectangular reticle.

23. The non-equilateral rectangular reticle container of claim 22, wherein the base further comprises a plurality of reticle pre-alignment windows for retrieving an alignment mark on the non-equilateral rectangular reticle.

24. The non-equilateral rectangular reticle container of claim 22, further comprising a gas diffusion device disposed inside the outer pod and configured to comprise a flow path and a gas diffusion component in communication with each other and disposed between the shell and the door, allowing the flow path to deliver gas to the gas diffusion component to blow the gas toward the cover of the inner pod.

25. The non-equilateral rectangular reticle container of claim 24, wherein the gas diffusion component disposed on an underside of a ceiling of the shell, with the flow path disposed at an end of the gas diffusion component and extending along an inner sidewall of the shell to an opening on a bottom of the door.

26. The non-equilateral rectangular reticle container of claim 24, wherein an air chamber is disposed between the flow path and the gas diffusion component.

27. The non-equilateral rectangular reticle container of claim 25, wherein a sealing element is disposed at a junction between the flow path and the openings of the door.

28. A non-equilateral rectangular reticle container, for receiving a non-equilateral rectangular reticle, comprising:
a shell; and
a door, wherein the door and the shell are capable of opening and closing relative to each other and define a receiving space, and the door has a length and a width equal to those of the shell respectively, with the receiving space receiving the non-equilateral rectangular reticle,
wherein the length and the width are 1.25 to 2.5 times a length of the non-equilateral rectangular reticle.
